(19) United States
(12) Patent Application Publication
(10) Pub. No.: US 2014/0035693 A1
(43) Pub. Date: Feb. 6, 2014

(54) METHOD AND APPARATUS FOR IMPLEMENTING HIGH-ORDER MODULATION SCHEMES USING LOW-ORDER MODULATORS

(71) Applicants: Zheng Li, Livingston, NJ (US); Rong Zhang, Nanjing (CN); Guoyong Chen, Nanjing (CN); Doug Clark, Mendham, NJ (US); Hai Chen, Montville, NJ (US); Yu Wan, Nanjing (CN); Jiaguan Leng, Nanjing (CN); Marc Shelton, Palatine, IL (US)

(72) Inventors: Zheng Li, Livingston, NJ (US); Rong Zhang, Nanjing (CN); Guoyong Chen, Nanjing (CN); Doug Clark, Mendham, NJ (US); Hai Chen, Montville, NJ (US); Yu Wan, Nanjing (CN); Jiaguan Leng, Nanjing (CN); Marc Shelton, Palatine, IL (US)

(73) Assignee: ALCATEL LUCENT, Paris (FR)

(21) Appl. No.: 14/111,582

(22) PCT Filed: Apr. 14, 2011
(86) PCT No.: PCT/CN11/72802

§ 371 Date: Oct. 14, 2013

(51) Int. Cl. H03C 5/00

(52) U.S. Cl. CPC H03C 5/00
USPC 332/103

(57) ABSTRACT

A processing device includes a plurality of modulators, the plurality of modulators performing modulation according to a first modulation scheme, a combiner configured to combine outputs from the plurality of modulators, and a signal processor configured to receive a bit stream and convert the bit stream into a plurality of input signals for the plurality of modulators such that the combiner generates a modulated output according to a second modulation scheme. The plurality of modulators may be low order modulators and a modulation schemes of the modulated output may include, for example, rotated quadrature phase shift keying (QPSK), pulse amplitude modulation (PAM), high order quadrature amplitude modulation (QAM), and multi-resolution high order quadrature amplitude modulation (M-QAM).

### BACKGROUND OF THE INVENTION

1. Field

Example embodiments relate generally to implementing signal modulation schemes.

2. Related Art

Wireless communications networks provide wireless coverage for mobiles traveling within geographical areas covered by the communications network. Wireless communications networks include base station (BS) for transmitting data to mobiles via a wireless downlink connection. A mobile can transmit data to a BS via a wireless uplink connection. Both BSs and mobiles modulate data before transmitting the data. There are many different types of modulation schemes including, for example, binary phase shift keying (BPSK), quadrature phase shift keying (QPSK), quadrature amplitude modulation (QAM), and pulse amplitude modulation (PAM). Each of these modulation schemes is desirable for certain types of transmission. Further, implementation of each of these schemes may require different hardware configurations within the base station or mobile implementing the scheme.

### SUMMARY

Example embodiments are directed to an apparatus and method for implementing modulation schemes using low order modulators.

According to an embodiment, a processing device includes a plurality of modulators, the plurality of modulators each performing modulation according to a same first modulation scheme, a combiner configured to combine outputs from the plurality of modulators and to produce a modulated output based on the combined outputs of the plurality of modulators; and a signal processor. The signal processor is configured to receive a bit stream, convert the bit stream into a plurality of input signals for the plurality of modulators, and to provide the plurality of input signals to the plurality of modulators in such a manner that the combiner generates the modulated output according to a second modulation scheme

According to an embodiment, the first modulation scheme is a phase shift keying (QPSK) scheme and the second scheme is a rotated QPSK scheme. The plurality of modulators includes at least first and second modulators. The signal processor is configured to provide a first input signal from among the plurality of input signals to a Q branch of the first modulator and to provide a fixed signal to an I branch of the first modulator such that the first modulator generates a first output, the signal processor is configured to provide a second input signal from among the plurality of input signals to an I branch of the second modulator and to provide a fixed signal to a Q branch of the second modulator such that the second modulator generates a second output, and the combiner is configured to generate the modulated output by combining the first and second outputs.

According to an embodiment, the first modulation scheme is a quadrature phase shift keying (QPSK) scheme and the second scheme is a pulse amplitude modulation (PAM) scheme. The plurality of modulators includes at least first and second modulators. The signal processor is configured to provide a first input signal from among the plurality of input signals to an I branch of the first modulator and to provide a fixed signal to a Q branch of the first modulator such that the first modulator generates a first output, the signal processor is configured to provide a second input signal from among the plurality of input signals to an I branch of the second modulator and to provide a fixed signal to a Q branch of the second modulator such that the second modulator generates a second output, and the combiner is configured to generate the modulated output by combining the first and second outputs.

According to an embodiment, the first modulation scheme is a quadrature phase shift keying (QPSK) scheme and the second scheme is a pulse amplitude modulation (QAM) scheme. The plurality of modulators includes at least first and second modulators. The signal processor is configured to provide a first input signal from among the plurality of input signals to an I branch of the first modulator and to provide a second input signal from among the plurality of input signals to a Q branch of the first modulator such that the first modulator generates a first output, the signal processor is configured to provide a third input signal from among the plurality of input signals to an I branch of the second modulator and to provide a fourth input signal from among the plurality of input signals to a Q branch of the second modulator such that the second modulator generates a second output, and the combiner is configured to generate the modulated output by combining the first and second outputs.

According to an embodiment, a method of modulating a bit stream includes converting the bit stream into a plurality of input signals; providing the plurality of input signals to a plurality of modulators, each of the plurality of modulators performing modulation according to a same first modulation scheme, generating outputs from the plurality of modulators, and combining the outputs from the plurality of modulators to generate a modulated signal. The plurality of input signals are provided to the plurality of modulators in such a manner that the combining of the outputs generates the modulated signal according to a second modulation scheme.

According to an embodiment, the first modulation scheme is a quadrature phase shift keying (QPSK) scheme and the second modulation scheme is a rotated QPSK scheme. The plurality of modulators includes at least first and second modulators. The generating step includes generating a first output from the first modulator by providing a first input signal from among the plurality of input signals to a Q branch of the first modulator and providing a fixed signal to an branch of the first modulator, and generating a second output from the second modulator by providing a second input signal from among the plurality of input signals to an I branch of the second modulator and providing a fixed signal to a Q branch of the second modulator.

According to an embodiment, the first modulation scheme is a quadrature phase shift keying (QPSK) scheme and the second modulation scheme is a pulse amplitude modulated (PAM) scheme.

The plurality of modulators includes at least first and second modulators. The generating step includes generating a first output from the first modulator by providing a first input signal from among the plurality of input signals to an I branch of the first modulator and providing a fixed signal to a Q branch of the first modulator, and generating a second output from the second modulator by providing a second input signal from among the plurality of input signals to an I branch of a second modulator and providing a fixed signal to a Q branch of the second modulator.

According to an embodiment, the first modulation scheme is a quadrature phase shift keying (QPSK) scheme and the second modulation scheme is a quadrature amplitude modulated (QAM) scheme. The plurality of modulators includes at least first and second modulators. The generating step includes generating a first output from the first modulator by providing a first input signal from among the plurality of input signals to a Q branch of a first modulator and providing a second input signal from among the plurality of input signals to an I branch of the first modulator, and generating a second output from the second modulator by providing a third input signal from among the plurality of input signals to an I branch of the second modulator and providing a fourth input signal from among the plurality of input signals to a Q branch of the second modulator.

### BRIEF DESCRIPTION OF THE DRAWINGS

Example embodiments of the present invention will become more fully understood from the detailed description provided below and the accompanying drawings, wherein like elements are represented by like reference numerals, which are given by way of illustration only and thus are not limiting of the present invention and wherein:

FIG. 1 illustrates a portion of a wireless communications network according to an embodiment.

FIG. 2 illustrates an example structure of a baseband processor system which may be used in either a BS or a mobile, according to an example embodiment.

FIG. 3 illustrates an example operation of a digital signal processor (DSP) unit and an application specific integrated circuit (ASIC) unit for implementing a quadrature phase shift keying (QPSK) modulation scheme.

FIG. 4 illustrates an example operation of a DSP unit and an ASIC unit for implementing a binary phase shift keying (BPSK) modulation scheme.

FIG. 5 illustrates an example configuration of a DSP unit and an ASIC unit for implementing a rotated QPSK scheme according to AN example embodiment.

FIG. 6 illustrates a method of implementing a rotated QPSK scheme using the configuration illustrated in FIG. 5.

FIGS. 7A and 7B illustrate example configurations of a DSP unit and an ASIC unit for implementing 4-pulse amplitude modulated (PAM) and 8-PAM schemes according to an example embodiment.

FIG. 8 illustrates a method of implementing a PAM scheme using the configuration illustrated in FIG. 7.

FIG. 9 illustrates an example configuration of a DSP unit and an ASIC unit for implementing a 16-QAM scheme according to an example embodiment.

FIG. 10 illustrates a method of implementing a QAM scheme according to an example embodiment.

FIG. 11 illustrates a vector representation for explaining the 16-QAM constellation corresponding to the output signal Tx illustrated in FIG. 9.

FIG. 12 illustrates a constellation for explaining a multi resolution QAM scheme according to an example embodiment.

FIG. 13 illustrates an example configuration of a DSP and ASIC unit 220 for implementing a 64-QAM scheme according to an example embodiment.

FIG. 14 is a diagram for explaining a system for implementing high order QAM schemes.

### DETAILED DESCRIPTION OF EXAMPLE EMBODIMENTS

Various example embodiments of the present invention will now be described more fully with reference to the accompanying drawings in which some example embodiments of the invention are shown.

Detailed illustrative embodiments of the present invention are disclosed herein. However, specific structural and functional details disclosed herein are merely representative for purposes of describing example embodiments of the present invention. This invention may, however, be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

As used herein, the term mobile may be considered synonymous to, and may hereafter be occasionally referred to, as a terminal, access terminal (AT), mobile unit, mobile station, mobile user, user equipment (UE), subscriber, user, remote station, access terminal, receiver, etc., and may describe a remote user of wireless resources in a wireless communication network. The term base station (BS) may be considered synonymous to and/or referred to as a base transceiver station (BTS), NodeB, extended Node B (eNB), femto cell, access point, etc. and may describe equipment that provides the radio baseband functions for data and/or voice connectivity between a network and one or more users.

Exemplary embodiments are discussed herein as being implemented in a suitable computing environment. Although not required, exemplary embodiments will be described in the general context of computer-executable instructions, such as program modules or functional processes, being executed by one or more computer processors or CPUs. Generally, program modules or functional processes include routines, programs, objects, components, data structures, etc. that performs particular tasks or implement particular abstract data types.

The program modules and functional processes discussed herein may be implemented using existing hardware in existing communication networks. For example, program modules and functional processes discussed herein may be implemented using existing hardware at existing network elements or control nodes (e.g., a BS or mobile shown in FIG. 1). Such existing hardware may include one or more digital signal processors (DSPs), application-specific-integrated-circuits (ASICs), field programmable gate arrays (FPGAs) computers or the like.

In the following description, illustrative embodiments will be described with reference to acts and symbolic representations of operations (e.g., in the form of flowcharts) that are performed by one or more processors, unless indicated otherwise. As such, it will be understood that such acts and operations, which are at times referred to as being computer-executed, include the manipulation by the processor of electrical signals representing data in a structured form. This manipulation transforms the data or maintains it at locations in the memory system of the computer, which reconfigures or otherwise alters the operation of the computer in a manner well understood by those skilled in the art.

FIG. 1 illustrates a portion of a wireless communication network 100. The wireless communication network 100 may follow, for example, a universal mobile telecommunications system (UMTS), wideband code division multiple access (W-CDMA), or long term evolution (LTE) protocol. The wireless communication network 100 may include a mobile 110 and a base station (BS) 120. The BS 120 may provide wireless coverage for the mobile 100 within a cell or geographical region associated with the BS 120. Accordingly, the BS 120 and the mobile 110 are both capable of transmitting and receiving data to and from one another, wirelessly. Data that is to be transmitted from either the mobile 110 or the BS 120 is first modulated before being sent over the air in the form of a radio signal. In order to perform this modulation, both the BS 120 and the mobile 110 may include a baseband processor system.

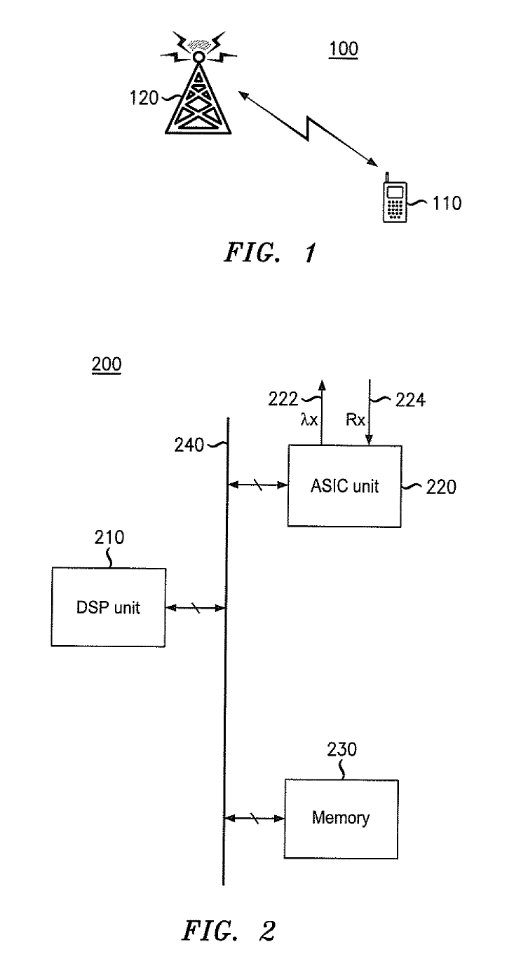

FIG. 2 illustrates an example structure of a baseband processor system 200, which may be used in either a BS or a mobile, according to an example embodiment. Referring to FIG. 2 the baseband processor system 200 may include a digital signal processing (DSP) unit 210, an application specific integrated circuit (ASIC) unit 220, and a memory unit 230.

The memory unit 230 may be any known type of memory device including, for example an SRAM type memory device.

The DSP unit 210 includes, for example, a processor capable of processing signals. For example, the DSP unit 210 includes the necessary hardware to perform serial-to-parallel conversion and Gray code conversion on input bit streams. The DSP unit 210 is capable of performing processing operations on signals based on, for example, executable instructions included in a program. Programs for controlling the DSP unit 210 are stored in, for example, the memory unit 230. The DSP unit 210 is be connected to the ASIC unit 220 and the memory unit 230 via, for example, a bus 240. The DSP unit 210 is capable of sending and/or receiving data and control signals to and/or from the ASIC unit 220 and the memory unit 230 using, for example, the bus 240. As will be discussed in greater detail below, the DSP unit 210 is capable of sending control signals to the ASIC unit 220 to control the operation of the ASIC unit 220. For example, the DSP unit 210 is capable of controlling inputs of modulators within the ASIC unit 220. The DSP unit 210 is also capable of controlling amplitudes of outputs of modulators within the ASIC 220. An example structure of the DSP unit 210 is discussed in “3G UMTS Wireless System Physical Layer: Baseband Processing Hardware Implementation Perspective.” IEEE Communications Magazine, September 2006, pp. 52˜58, the entirety of which is incorporated herein by reference.

The ASIC unit 220 includes hardware for modulating input bit streams. The ASIC unit 220 includes one or more modulators. The modulators may be, for example, quadrature phase shift keying (QPSK) modulators. Each of the modulators is capable of receiving input signals and outputting a modulated signal. The modulators are capable of outputting modulated signals at different amplitudes. The amplitudes at which each of the modulators outputs modulated signals may be controlled by the DSP unit 210.

The ASIC unit 220 is capable of receiving and transmitting signals, for example modulated signals, through Rx input interface 224 and Tx output interface 222, respectively. The ASIC unit 220 is capable of combining multiple signals to output a combined signal from the Tx output interface 222. For example, each of the QPSK modulators in the ASIC unit 220 may generate a separate modulated output, and each of these separate modulated outputs may be fed to the Tx output interface 222 such that the separate outputs are combined at, and output from, the Tx output interface 222 as a combined modulated output. The DSP unit 210 is capable of controlling the ASIC unit to combine modulated outputs and to output the combined modulated signal. An example structure of the ASIC unit 220 is discussed in “An Eight-User UMTS Channel Unit Processor for 3GPP Base Station Applications,” IEEE J. Solid-State Circuits, vol. 39, No. 9, September 2004, the entirety of which is incorporated herein by reference.

According to an example embodiment, the baseband processor system 200 is capable of implementing multiple types of modulation schemes without requiring any redesign of ASIC transmitter hardware (Tx ASIC). For example, as will be discussed in greater detail below, the baseband processor system 200, according to example embodiments, is capable of implementing a rotated QPSK scheme, pulse amplitude modulation (PAM) schemes, and quadrature amplitude modulation (QAM) schemes. The PAM schemes include, but are not limited to, the 4-PAM scheme. The QAM schemes include, but are not limited to, 16-QAM and high order modulation (HOM) schemes including 64-QAM. As will be discussed in greater detail below, by providing appropriate programming of the DSP unit 210, all the schemes discussed above may be implemented using, for example, only one or more QPSK modulators in the ASIC unit 220. Thus, according to an example embodiment, existing baseband processor systems can implement an extended set of modulation schemes, including HOM schemes, using low-order modulators, and thus, new hardware is not required.

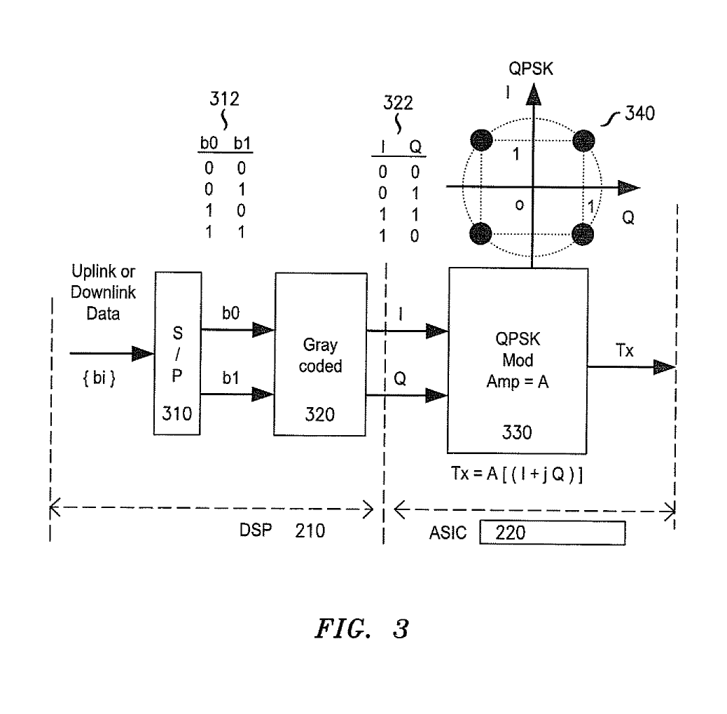

Capabilities of the DSP unit 210 and the ASIC unit 220 will now be discussed in greater detail below with reference to FIGS. 3-14.

### Implementing QPSK Modulation

FIG. 3 illustrates an example operation of the DSP unit 210 and the ASIC unit 220 for implementing a QPSK modulation scheme. As is illustrated in FIG. 3 the DSP unit 210 is capable of implementing a serial-to-parallel (S/P) conversion function 310 and a Gray code conversion function 320. The S/P conversion function 310 receives data in the form of a bit stream bi, and produces parallel data in the form of first and second bit streams, b0 and b1, based on the bit stream bi. The data bi may be uplink data, in the case of transmission from a mobile, or downlink data, in the case of transmission from a BS. The Gray code conversion function 320 receives the first and second bit streams b0 and b1, converts the bit streams into Gray code, and outputs signals I and Q as the Gray code converted bit streams b0 and b1. Bit streams I and Q correspond to in-phase (I) and quadrature (Q) branch inputs of a QPSK modulator 330. Table 312 in FIG. 3 illustrates bit streams b0 and b1 corresponding to values 0-3 before Gray code conversion and table 322 illustrates bit streams I and Q corresponding to values 0-3 after Gray code conversion. As is illustrated by table 322 in FIG. 3, after Gray code conversion, only one bit changes at a time between adjacent two-bit representations of values 0-3.

The gray code converted bit streams are provided to a QPSK modulator 330 included in the ASIC unit 220. As explained above, Bit streams I and Q correspond to in-phase (I) and quadrature (Q) branch inputs of a QPSK modulator 330. The QPSK modulator 330 performs QPSK modulation on the I and Q bit streams. The output signal, Tx, may be expressed as Tx=A(I+jQ), where A is an amplitude of the output signal Tx, and j²=−1.

QPSK constellation 340 illustrates a constellation corresponding to the output signal Tx assuming the amplitude A is set to 1.

### Implementing BPSK Modulation

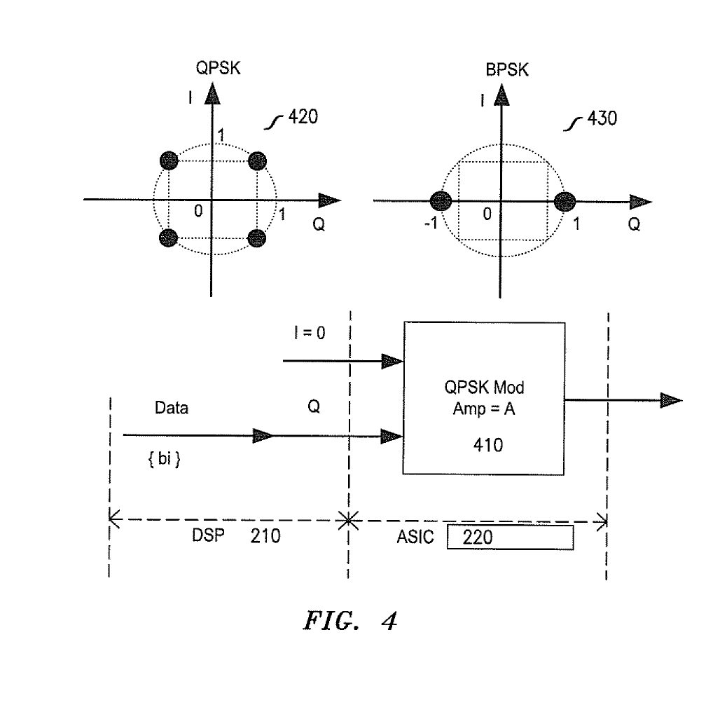

FIG. 4 illustrates an example configuration of the DSP unit 210 and the ASIC unit 220 for implementing a BPSK modulation scheme.

For example, as is illustrated in FIG. 4, the DSP unit 210 provides all the bit stream bi to a Q branch of a QPSK modulator 410 included in the ASIC unit 220. The DSP unit 210 maintains a fixed logical value of 0 to an I branch input of the QPSK modulator 410. The QPSK modulator responds by producing an output which is effectively a BPSK output. That is, in contrast to the full QPSK constellation illustrated by FIG. 420, the symbols output by the QPSK modulator subject to the fixed input as described above will be limited to a BPSK constellation as illustrated in FIG. 430.

### Implementing Rotated QPSK Modulation

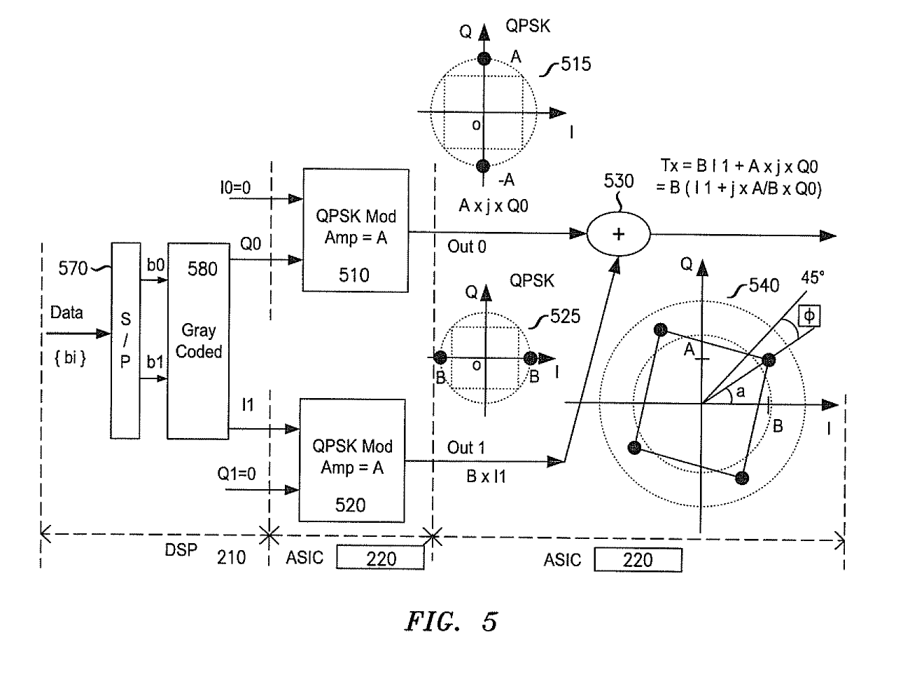

FIG. 5 illustrates an example configuration of the DSP unit 210 and the ASIC unit 220 for implementing a rotated QPSK scheme according to an example embodiment.

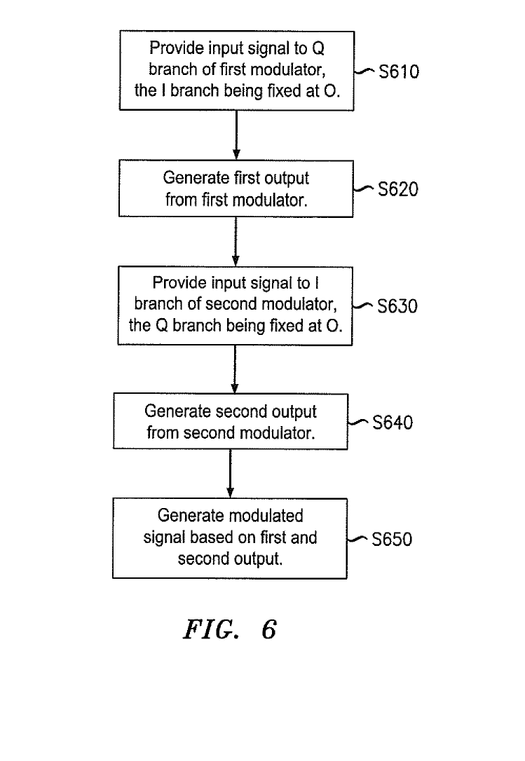

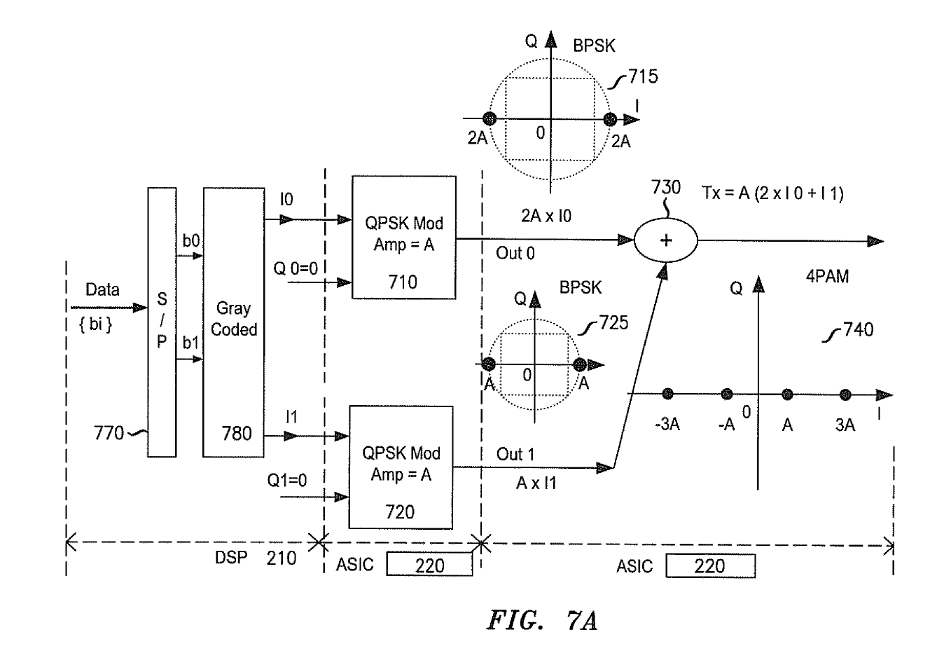

For example, as is illustrated in FIG. 5, QPSK modulation may be implemented by using first and second QPSK modulators 510 and 520 included in the ASIC unit 220. Further, as is illustrated in FIG. 5, the DSP unit 210 may perform a serial-to-parallel S/P conversion function 570 on an input bit stream bi to create parallel bit streams b0 and b1. Further, the DSP unit 210 may perform a Gray code function 580 on parallel bit streams b0 and bi before providing the converted bit streams to the first and second QPSK modulators 510 and 520 of the ASIC unit 220. FIG. 6 illustrates a method of implementing a rotated QPSK scheme using the configuration illustrated in FIG. 5.

Referring to FIG. 6, in step S610, an input signal is provided to a Q branch input of a first modulator, which has the I branch input fixed at 0. In step S620, a first output is generated from the first modulator.

For example, as is illustrated in FIG. 5, the DSP unit 210 outputs the Gray code converted bit stream b0 to a Q branch input of the first QPSK modulator 510(labeled in FIG. 5 as Q0), while configuring the corresponding I branch input to be fixed at, for example, 0V for the first QPSK modulator 510, (labeled in FIG. 5 as I0). Further, the first modulator 510 generates a first output signal Out0. The first output signal Out0 may be defined as Out0=A×j×Q0, where A is an amplitude of the signal output by the first QPSK modulator 510 and j²=−1. The first output signal Out0 may take values constructing the BPSK constellation 515.

Returning to FIG. 6, in step S630, an input signal is provided to an I branch input of a second modulator, which has the Q branch input fixed at 0. In step S640, a second output is generated from the second modulator. Though steps S610-S640 are illustrated as being performed in series, it will be understood that steps S610-S620 may be performed in parallel with steps S630-S640.

For example, as is illustrated in FIG. 5, the DSP unit 210 outputs the Gray-code-converted bit stream b1 and directs it to an I branch input of the second QPSK modulator 520 (labeled in FIG. 5 as I1) while configuring the corresponding Q branch input to be fixed at, for example, 0V for the second QPSK modulator 520 (referred to in FIG. 5 as Q1). Further, the second modulator 520 generates a second output signal Out1. The second output signal Out1 may be defined as Out1=B×I1, where B is an amplitude of the signal output by the second QPSK modulator 520. The second output signal Out1 may take values constructing the BPSK constellation 525.

Returning to FIG. 6, in step S650, a modulated signal is generated based on the first and second outputs.

For example, as is illustrated in FIG. 5, the first and second output signals Out0 and Out1, may be combined using an adder 530 to generate a modulated signal Tx. The adder 530 may be, for example, the output interface 222 of the ASIC unit 220. The modulated signal Tx may be defined as Tx=B(I1+j×(A/B)×Q0). The possible values of the modulated signal Tx correspond to a QPSK constellation having 4 points. These constellation points may be rotated. For example a constellation point (A,B) can be rotated θ degrees to create a rotated constellation point (X, Y) according to the following equation:

$$( \begin{matrix}X \\ Y\end{matrix} ) = ( \begin{matrix}cos Θ & sin Θ \\ - sin Θ & cos Θ\end{matrix} ) ( \begin{matrix}A \\ B\end{matrix} ) , \qquad ( 1 )$$

where θ is defined as π/4−α, and α=arctan(A/B).

By rotating constellation points corresponding to the modulated signal Tx by an angle θ, a rotated QPSK constellation can be created. Constellation 540 is an example of a QPSK constellation rotated by an angle θ. Further, by adjusting the angle θ with DSP software programming, an optimum modulation diversity can be obtained to reduce or minimize bit error rate (BER). For example, research results that are useful in this regard have been reported in “Proposed Text of Coding-Rotated-Modulation OFDM system for the IEEE 802.16m Amendment”, IEEE C802.16m-09/0414, and “Signal Space Diversity: A Power-and Bandwidth-Efficient Diversity Technique for the Rayleigh Fading Channel”, IEEE TRANS ON INFOR THEORY, VOL. 44, NO. 4, JULY 1998, both of which are incorporated herein by reference in their entirety. As being theoretically studied by the above papers, the modulation diversity can be achieved by rotating the signal constellation, and the modulation diversity can be used to improve the performance of QPSK modulation over fading channels. With the multidimensional rotated QAM or (phase shift keying) PSK constellations, very high diversity orders can be achieved and this results in an almost Gaussian performance over the fading channel. This multidimensional modulation scheme is essentially uncoded and enables one to trade diversity for system complexity at no power or bandwidth expense. As is described above, the DSP 210 and ASIC 220 are capable of implementing the rotated modulation scheme.

### Implementing PAM

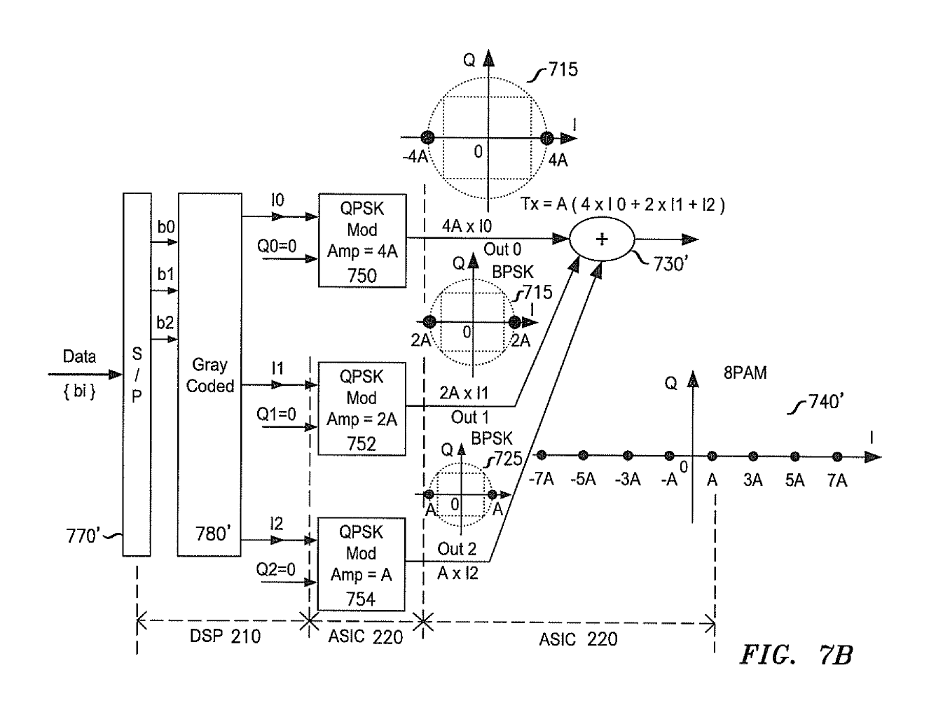

FIG. 7A illustrates an example configuration of the DSP unit 210 and the ASIC unit 220 for implementing a PAM scheme according to an example embodiment.

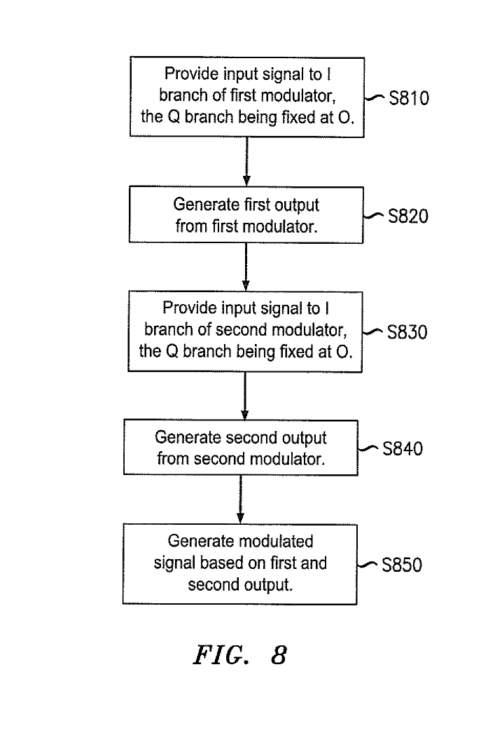

For example, as is illustrated in FIG. 7A, a 4-PAM scheme may be implemented by using first and second QPSK modulators 710 and 720 included in the ASIC unit 220. FIG. 8 illustrates a method of implementing a PAM scheme using the configuration illustrated in FIG. 7. Further, as is illustrated in FIG. 7A, the DSP unit 210 may perform a S/P conversion function 770 on an input bit stream bi to create parallel bit streams b0 and b1. Further, the DSP unit 210 may perform a Gray code function 780 on parallel bit streams b0 and b1 before providing the converted bit streams to the first and second QPSK modulators 710 and 720 of the ASIC unit 220.

Referring to FIG. 8, in step S810, an input signal is provided to an I branch input of a first modulator which has a Q branch input fixed at 0. In step S820, a first output is generated from the first modulator.

For example, as is illustrated in FIG. 7A, the DSP unit 210 outputs the bit stream b0 to an I branch input of the first QPSK modulator 710 (labeled in FIG. 7A as 10), while configuring the corresponding Q branch input to be fixed at, for example, 0V for the first QPSK modulator 710, (labeled in FIG. 7A as Q0). Further, the first modulator 710 generates a first output signal Out0. The first output signal Out0 may be defined as Out0=2A×TO, where 2A is an amplitude of the signal provided as output by the first QPSK modulator 710, j²=−1, and A is a power level scaling factor for the first and second QPSK modulators 710 and 720. The factor A may be equal to, for example, 0.4472. The first output signal Out0 may take values 2A or −2A to construct the BPSK constellation 715.

Returning to FIG. 8, in step S830, an input signal is provided to an I branch input of a second modulator, which has a Q branch input fixed at 0. In step S840, a second output is generated from the second modulator. Although steps S810-S840 are illustrated as being performed in series, it will be understood that steps S810-S820 may be performed in parallel with steps S830-S840.

For example, as is illustrated in FIG. 7A, the DSP unit 210 outputs the bit stream b91 to an I branch input of the second QPSK modulator 720 (labeled in FIG. 7A as I1), while configuring the corresponding Q branch input to be fixed at, for example, 0V for the second QPSK modulator 720, (labeled in FIG. 7A as Q1). Further, the second modulator 720 generates a second output signal Out1. The second output signal Out1 may be defined as Out1=A×I1, where A is the power level scaling factor for the first and second QPSK modulators 710 and 720, and an amplitude of the signal output by the second QPSK modulator 720, Out1, is equal to the power level scaling factor A. The second output signal Out1 may take values A or −A to construct the BPSK constellation 725. In the example illustrated in FIG. 7A, the amplitude of the first output signal Out0 may be twice the amplitude of the second output signal, Out1.

Returning to FIG. 8, in step S850, a modulated signal is generated based on the first and second outputs.

For example, as is illustrated in FIG. 7, the first and second output signals, Out0 and Out1, of the first and second QPSK modulators 710 and 720 are combined using an adder 730 to generate a modulated signal Tx. The adder 730 may be, for example, the output interface 222 of the ASIC unit 220. The modulated signal Tx may be defined as Tx=A(2×I0×I1). The output signal Tx takes values constructing a constellation 740. As is illustrated by constellation 740, the modulated signal Tx takes values constructing from a 4-PAM constellation.

Although the examples illustrated above with respect to FIGS. 7A and 8 have been discussed with specific reference to a 4-PAM scheme, the DSP unit 210 and the ASIC unit 220 are capable of implementing other PAM schemes including, for example, 8-PAM or 16-PAM, using QPSK modulators.

For example, FIG. 7B illustrates an example configuration of the DSP unit 210 and the ASIC unit 220 for implementing a 8-PAM scheme. The configuration illustrated in FIG. 7B is similar to that illustrated in FIG. 7A. However, instead performing S/P processing to generate two parallel bit streams, as illustrated in FIG. 7A, the DSP unit 210 may perform a S/P conversion function 770′ on an input bit stream bi to create three parallel bit streams b0-b2. Further, the DSP unit 210 may perform a Gray code function 780′ on parallel bit streams b0-b2 before providing the converted bit streams to the first, second and third QPSK modulators 750, 752 and 754 of the ASIC unit 220.

The first QPSK modulator 750 receives Gray code converted input b0 at an I branch input 10 from the DSP 210 while the corresponding Q branch input Q0 is configured to be fixed at, for example, 0V by the DSP 210. The first output Out0 may be defined by Out0=4A×I0. The second QPSK modulator 752 receives Gray code converted input b1 at an I branch input 11 from the DSP 210 while the corresponding Q branch input Q1 is configured to be fixed at, for example, 0V by the DSP 210. The second output Out1 may be defined by Out1=2A×I1. The third QPSK modulator 754 receives Gray-code-converted input b2 at an I branch input 12 from the DSP 210 while the corresponding Q branch input Q2 is configured to be fixed at, for example, 0V by the DSP 210. The third output Out2 may be defined by Out2=A×I2. The first through third outputs, Out0-Out2, of the first through third QPSK modulators 750-752 are combined by the adder 730′ to generate the modulated signal Tx. The adder 730′ may be, for example, the output interface 222 of the ASIC unit 220. The modulated signal Tx may be defined as Tx=A(4×I0+2×I1+I2). As is illustrated by constellation 740′ in FIG. 7B, the output signal Tx may take values constructing an 8-PAM constellation. Accordingly, the DSP unit 210 and ASIC unit 220 are capable of implementing an 8-PAM scheme using no more than three QPSK modulators.

In the example illustrated in FIG. 7B, the amplitude of the first output signal Out0 may be twice the amplitude of the second output signal, Out1, and the amplitude of the second output signal Out1 may be twice the amplitude of the third output signal, Out2.

Thus, according to an example embodiment, high order PAM schemes can be implemented using QPSK modulators in an ASIC unit.

### Implementing QAM

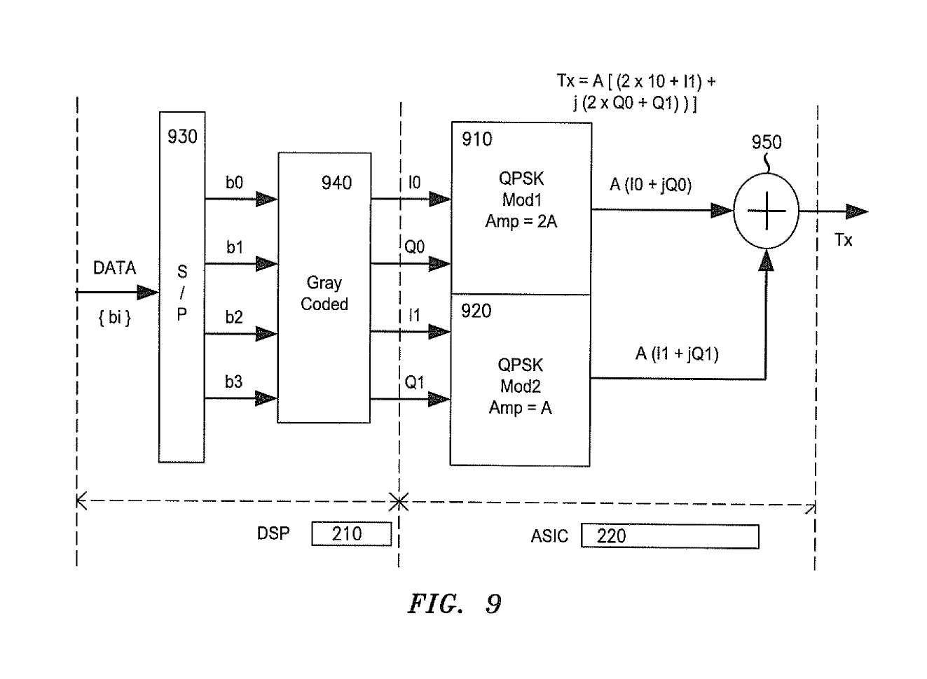

FIG. 9 illustrates an example configuration of the DSP unit 210 and the ASIC unit 220 for implementing a 16-QAM scheme according to an example embodiment.

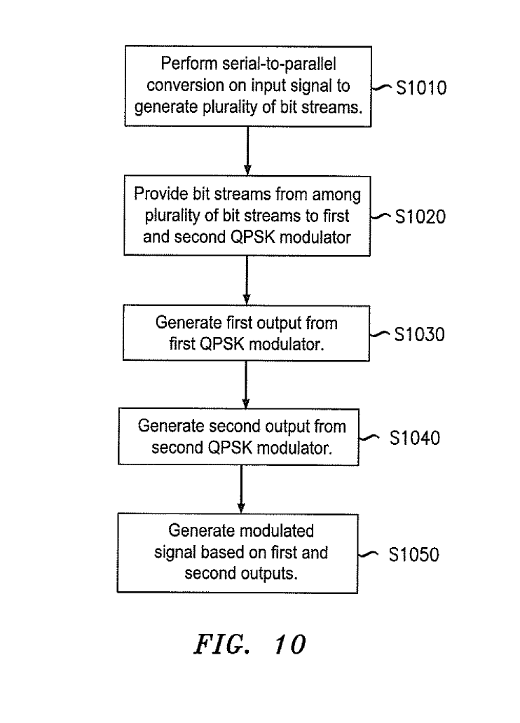

For example, as is illustrated in FIG. 9, a 16-QAM scheme may be implemented by using first and second QPSK modulators 910 and 920 included in the ASIC unit 220. FIG. 10 illustrates a method of implementing a QAM scheme. FIG. 10 will now be explained with reference to FIG. 9.

Returning to FIG. 10, in Step S1010 S/P conversion is performed on an input signal to generate a plurality of bit streams. In step S1020, bit streams, from among the plurality of bit streams, are provided to the first and second modulators.

For example, as is illustrated in FIG. 9, the DSP unit 210 may implement an S/P conversion function 930 and a Gray code conversion function 940. The S/P conversion function 930 performs S/P conversion on data received in the form of a bit stream bi, and produces parallel data in the form of first through fourth bit streams, b0-b3, based on the bit stream bi. Further, the Gray code conversion function 940 performs Gray code conversion on the first through fourth bit streams b0-b3. The Gray code conversion function 940 outputs Gray-code-converted bit streams b0-b1 to I branch and Q branch inputs of the first QPSK modulator 910 (labeled in FIG. 9 as I0 and Q0, respectively), and outputs Gray code converted bit streams b2-b3 to I branch and Q branch inputs of the second QPSK modulator 920 (labeled in FIG. 9 as 11 and Q1, respectively).

Returning to FIG. 10, in step S 1030, a first output is generated from the first QPSK modulator. In step S1040, a second output is generated from the second QPSK modulator. Although steps S1030 and S1040 are illustrated as being performed in series, it will be understood that step S 1030 and S 1040 may be performed in parallel.

For example, as illustrated in FIG. 9, the first QPSK modulator 910 generates a first output Out0. The first output Out0 may be based on the I branch and Q branch inputs of the first QPSK modulator 910, I0 and Q0, and may be defined as Out0=2A(I0+j×Q0), where A is a power level scaling factor for the first and second QPSK modulators 910 and 920. The factor A may be, for example, 0.3162. An amplitude of the signal output by the first QPSK modulator 910 is 2A, and j²=−1. Further, the second QPSK modulator 920 generates a second output Out1. The second output Out1 may be based on the I branch and Q branch inputs of the second QPSK modulator 920, I1 and Q1, and may be defined as Out1=A(I1+j×Q1), where an amplitude of the signal output by the first QPSK modulator 910 may be A and j²=−1. In the example illustrated in FIG. 9, the amplitude of the first output signal Out0 may be twice the amplitude of the second output signal, Out1.

Returning to FIG. 10, in step S1050, a modulated signal is generated based on the first and second outputs.

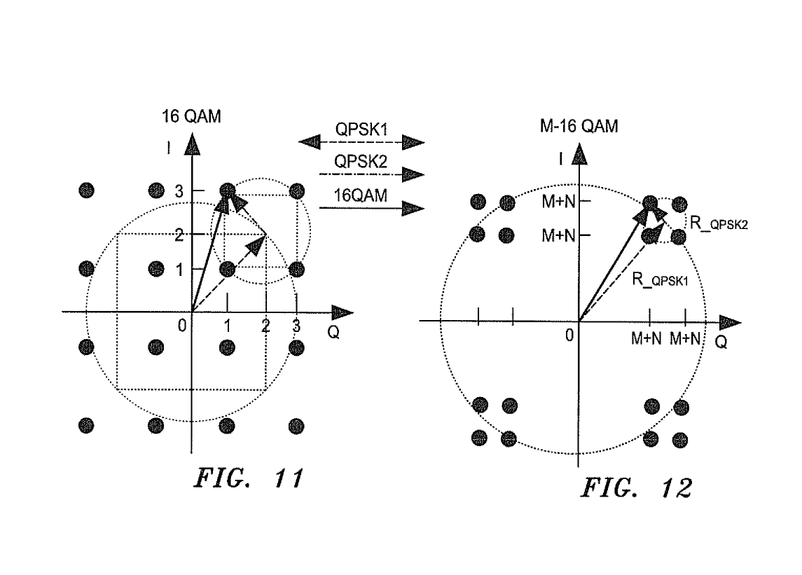

For example, as is illustrated in FIG. 9, the first and second output signals, Out0 and Out1, of the first and second QPSK modulators 910 and 920 are added using an adder 950 to generate a modulated signal Tx. The adder 950 may be, for example, the output interface 222 of the ASIC unit 220. The modulated signal Tx may be defined as Tx=A((2×I0×I1)+j(2×Q0+Q1)). The output signal Tx may take values constructing a 16-QAM constellation. FIG. 11 illustrates a 16-QAM constellation corresponding to the output signal Tx illustrated in FIG. 9.

Referring to FIG. 11, vectors QPSK1, QPSK2, and 16QAM are illustrated to explain how two QPSK modulators can be used to produce an output signal Tx which takes values constructing a 16-QAM constellation. Vector QPSK1 corresponds to the first output, Out0, of the first modulator 910 illustrated in FIG. 9 and has a magnitude R1. Vector QPSK1 illustrates one of the four constellation points which may represent the first output signal Out1 output from the first QPSK modulator 910. In the example illustrated in FIG. 11, the vector QPSK1 indicates the point (2A,2A). The points which may be reached by the vector QPSK1 are (+/−2A, +/−2A). The value 2A units corresponds to the amplitude of the first output signal Out1, which as is discussed above, is 2A.

Vector QPSK2 corresponds to the second output, Out1, of the second modulator 920 illustrated in FIG. 9 and has the magnitude R2. Vector QPSK2 illustrates one of the four constellation points. In our example, Vector QPSK2 is the sum of second output signal, i.e. Out2, from QPSK modulator 920 with the first output signal Out1. The points which may be reached by the vector QPSK2 are (+/−1A, +/−1A) with respect to the point (2A,2A). The value 1A unit corresponds to the amplitude of the second output signal Out2, which as is discussed above, is 1A.

The combination of the vectors QPSK1 and QPSK2 is represented by the vector 16QAM. As is illustrated in FIG. 11, by combining the first and second output signals Out0 and Out1 having respective amplitudes of 2A and A, every point on a 16-QAM constellation may be reached. Accordingly, the DSP unit 210 and ASIC 220 may implement a 16-QAM scheme using no more than 2 QPSK modulators.

Additionally, according to an example embodiment, the DSP unit 210 and ASIC 220 may implement a multi-resolution QAM scheme. FIG. 12 illustrates one constellation illustrative for the following discussion of a multi resolution QAM scheme according to an example embodiment.

Like FIG. 11, FIG. 12 illustrates a constellation corresponding to a 16-QAM scheme which may be implemented using, for example, two QPSK modulators. However, in the example illustrated in FIG. 12, the amplitudes of the two QPSK modulators are not necessarily set to 2A and A. The 16-QAM constellation illustrated in FIG. 12 may be generated by a first QPSK modulator having an output signal with an amplitude of M, and a second QPSK modulator having an output signal with an amplitude of N. As is illustrated in FIG. 12, the spacing of the constellation points in the 16-QAM constellation can be controlled based on the values chosen for amplitudes M and N. Similar to the description of first and second vectors QPSK1 and QPSK2 of FIG. 11, in FIG. 12, a vector R_QPSK1 corresponds with the output of the first modulator having the amplitude M, and the vectors R_QPSK2 corresponds with the output of the second modulator having the amplitude N. This allows for the generation of QAM constellations having multiple spacing types or resolutions. Multi-resolution QAM may be used with, for example, multimedia broadcast/multicast services (MBMS) for multiple input multiple output (MIMO) UMTS terrestrial radio access (UTRA) LTE systems.

The transmission signal Tx associated with the constellation illustrated in FIG. 12 may be defined by Tx=A((M×I0+N×I1)+j(M×Q0+N×Q1)), where A is the power level scaling factor of the first and second QPSK modulators, which, as noted above, provide respective output signals having amplitudes of M and N. The power level scaling factor A may be defined as A=1/\sqrt{(M−N)²+(M+N)²}.

Although the example illustrated in FIG. 12 is specifically directed to a multi-resolution 16 QAM constellation, it should be noted that this is merely exemplary and not limiting, and that other multi-resolution QAM schemes may be implemented. Thus, according to an example embodiment, a system operator of the wireless network 100 could determine a desired constellation spacing or resolution, and based on the desired constellation spacing or resolution, provide programming to the DSP unit 210 including the instructions necessary to cause the ASIC unit 220 set amplitudes of a number of QPSK modulators in accordance with the desired resolution.

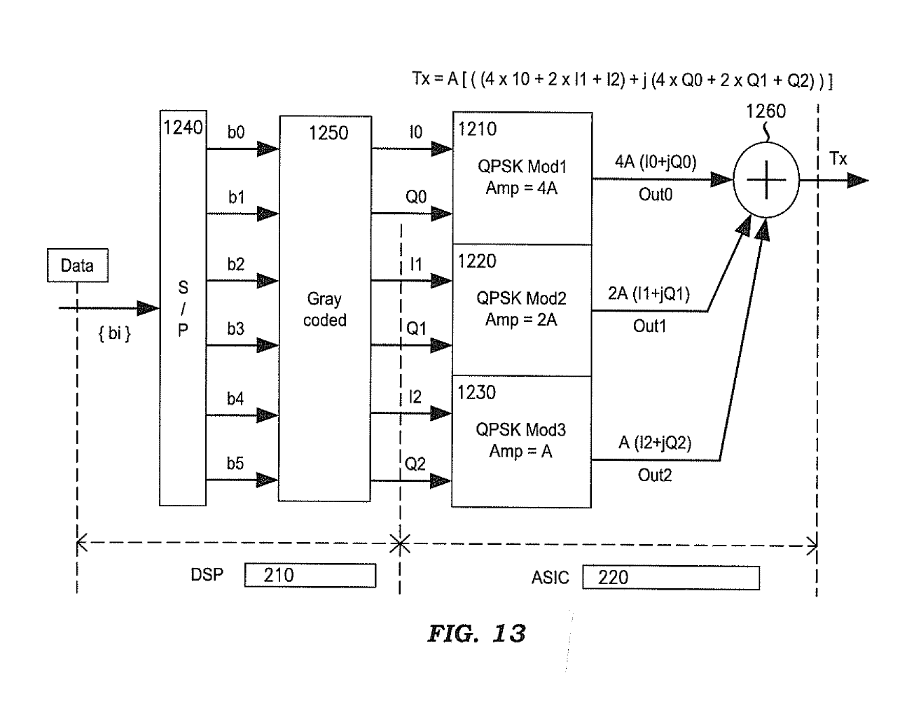

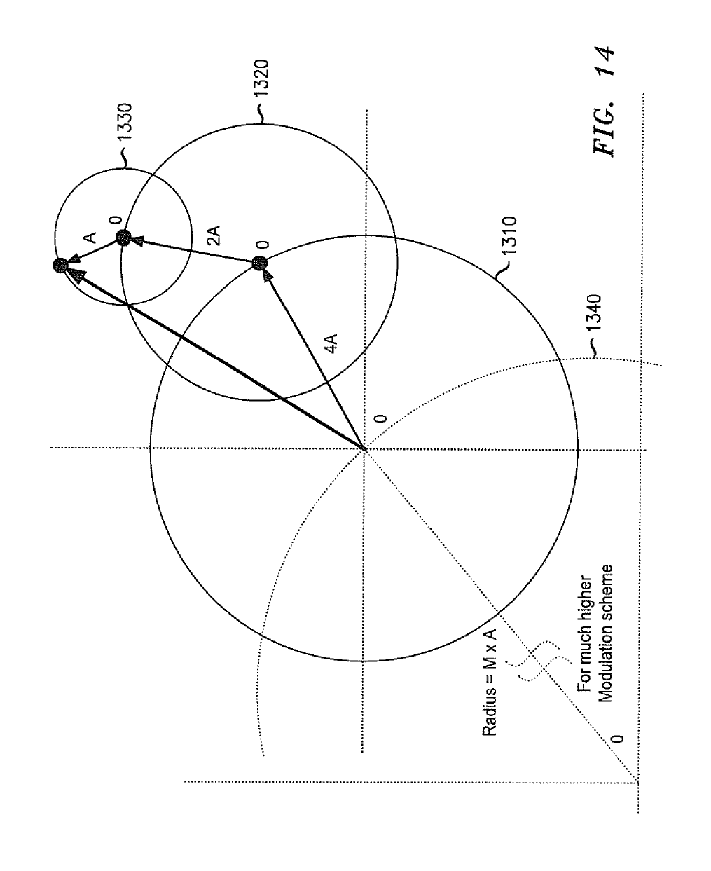

Further, according to an example embodiment, even higher order QAM schemes may be implemented. For example, FIG. 13 illustrates an example configuration of the DSP unit 210 and ASIC unit 220 for implementing a 64-QAM scheme.

The configuration illustrated in FIG. 13 is similar to that illustrated in FIG. 9. However, instead of performing S/P processing to generate four parallel bit streams, as illustrated in FIG. 9, the DSP unit 210 implements an S/P function 1240 which generates six parallel bit streams b0-b5. The DSP unit 210 may also implement a Gray code conversion function 1250 to perform. Gray code conversion on the bit streams b0-b5. Further, instead of utilizing two QPSK modulators, as illustrated in FIG. 9, first, second and third QPSK modulators, 1210, 1220 and 1230 are utilized in the ASIC unit 220. The first QPSK modulator 1210 receives Gray code converted inputs b0 and b1 at I branch input 10 and Q branch input Q0, and generates a first output, Out0. The first output Out0 may be defined by Out0=4A(I0+jQ0). The second QPSK modulator 1220 receives Gray code converted inputs b2 and b3 at I branch input I1 and Q branch input Q 1, and generates a second output, Out1. The second output Out1 may be defined by Out0=2A(I1±jQ1). The third QPSK modulator 1230 receives Gray code converted inputs b4 and b5 at I branch input 12 and Q branch input Q2, and generates a third output, Out2. The third output Out0 may be defined by Out0=A(I2+jQ2). The value A in the example illustrated in FIG.

13 is the power level scaling factor of the first through third QPSK modulators and may be equal to, for example, 0.1543. The first through third outputs, Out0-Out2, of the first through third QPSK modulators 1210-1230, are combined by the adder 1260 to generate the modulated signal Tx. The adder 1260 may be, for example, the output interface 222 of the ASIC unit 220. The modulated signal Tx may be defined as Tx=A((4×I0+2×I1+I2)+j(4×Q0+2×Q1+Q2)). The output signal Tx takes values from to a 64-QAM constellation. Accordingly, the DSP unit 210 and ASIC unit 220 are capable of implementing a 64-QAM scheme using no more than three QPSK modulators.

FIG. 14 is a diagram for explaining a system for implementing high order QAM schemes.

FIG. 14 illustrates first through third radiuses 1310, 1320 and 1330 corresponding to constellation points which may be reached by combining the outputs of QPSK modulators outputting signals having amplitudes of 4A, 2A and A, respectively. For example, the radiuses 1310, 1320 and 1330 may correspond to first through third output signals Out0, Out1, and Out2 output by first through third modulators 1210-1230 illustrated in FIG. 13. Accordingly, radiuses 1310, 1320 and 1330, when combined, can reach all 64 points of the 64-QAM constellation. FIG. 14 also illustrates a fourth radius 1340 having a value of M×A, where M may be any positive integer including for example, 8, 16 or 32. As is illustrated in FIG. 14, using only a plurality of QPSK modulators with appropriately set amplitudes, even higher order schemes including, for example, 256-QAM or 1024-QAM, can be implemented.

### General 2^{2M} QAM HOM Scheme

As is discussed above, using programs including the appropriate instructions at the DSP unit 210, the ASIC unit 220 can use QPSK modulators to implement multiple QAM schemes including HOM schemes like 64-QAM and 256-QAM. A general definition of a transmission signal Tx for QAM modulation schemes generated by the DSP unit 210 and ASIC unit 220 included in the baseband processor system 200 according to an example embodiment is represented by equation (2) below.

$$Tx = A {\sum }_{m}^{M} {2}^{m} ( {I}_{M - m - 1} + {jQ}_{M - m - 1} ) , \qquad ( 2 )$$

where M may be a positive integer equal to the number of QPSK modulators used to implement the QAM scheme, and m=0, 1, 2, 3 . . . (M−1).

Thus, according to an example embodiment the ASIC unit 220 including one or more low order QPSK modulators can be used to implement multiple types of modulation schemes including rotated QPSK schemes, PAM schemes, high-order QAM schemes and multi-resolution QAM schemes. Further, each of these schemes may be implemented by providing appropriate programming at the DSP unit 210, and without requiring changes to the hardware of the ASIC unit 220. Further, although, according to some example embodiments above, generating a modulated signal is described as being accomplished by combining outputs of modulators, it is to be understood that operations which may be used to accomplish this combination are not limited to addition, and may include other operations including, for example, subtraction, multiplication or division. Further, although, according to some example embodiments above, selected inputs of modulators are described as being configured to be fixed at 0V by the DSP 210, it is to be understood that the fixed value can be any value that prevents the inputs of the modulators receiving the fixed signal from causing variation in the output of the modulators.

The invention being thus described, it will be obvious that the same may be varied in many ways. Such variations are not to be regarded as a departure from the invention, and all such modifications are intended to be included within the scope of the invention.

What is claimed is:

1. A processing device comprising:
a plurality of modulators, the plurality of modulators each performing modulation according to a same first modulation scheme;
a combiner configured to combine outputs from the plurality of modulators and to produce a modulated output based on the combined outputs of the plurality of modulators; and
a signal processor configured to receive a bit stream, convert the bit stream into a plurality of input signals for the plurality of modulators, and to provide the plurality of input signals to the plurality of modulators in such a manner that the combiner generates the modulated output according to a second modulation scheme.

2. The processing device of claim 1, wherein:
the first modulation scheme is a phase shift keying (QPSK) scheme and the second scheme is a rotated QPSK scheme, and
the plurality of modulators includes at least first and second modulators.

3. The processing device of claim 2, wherein
the signal processor is configured to provide a first input signal from among the plurality of input signals to a Q branch of the first modulator and to provide a fixed signal to an I branch of the first modulator such that the first modulator generates a first output,
the signal processor is configured to provide a second input signal from among the plurality of input signals to an I branch of the second modulator and to provide a fixed signal to a Q branch of the second modulator such that the second modulator generates a second output, and
the combiner is configured to generate the modulated output by combining the first and second outputs.

4. The processing device of claim 2, wherein the signal processor is configured to provide first and second input signals to the first and second modulators and to control the first and second modulators to generate the first and second outputs having first and second amplitudes, respectively, the first and second amplitudes being selected to provide a desired amount of rotation for a rotated constellation (X,Y).

5. The processing device of claim 4, wherein the rotated constellation (X,Y) is defined as
$$( \begin{matrix}X \\ Y\end{matrix} ) = ( \begin{matrix}cos Θ & sin Θ \\ - sin Θ & cos Θ\end{matrix} ) ( \begin{matrix}A \\ B\end{matrix} ) ,$$
where A is the first amplitude, B is the second amplitude, Θ=π/4−α, and α=arctan(A/B).

6. The processing device of claim 2 wherein signal processor is configured such that the fixed signal provided to the first modulator prevents the I branch of the first modulator from causing variation in the output of the first modulator, and the fixed signal provided to the second modulator prevents the Q branch of the second modulator from causing variation in the output of the second modulator.

7. The processing device of claim 1, wherein
the first modulation scheme is a quadrature phase shift keying (QPSK) scheme and the second scheme is a pulse amplitude modulation (PAM) scheme, and
the plurality of modulators includes at least first and second modulators.

8. The processing device of claim 7, wherein
the signal processor is configured to provide a first input signal from among the plurality of input signals to an I branch of the first modulator and to provide a fixed signal to a Q branch of the first modulator such that the first modulator generates a first output,
the signal processor is configured to provide a second input signal from among the plurality of input signals to an I branch of the second modulator and to provide a fixed signal to a Q branch of the second modulator such that the second modulator generates a second output, and
the combiner is configured to generate the modulated output by combining the first and second outputs.

9. The processing device of claim 7 wherein the first and second modulators are configured such that an amplitude of the first output is twice an amplitude of the second output.

10. The processing device of claim 7 wherein the signal processor is configured such that the fixed signal provided to the first modulator prevents the Q branch of the first modulator from causing variation in the output of the first modulator, and the fixed signal provided to the second modulator prevents the Q branch of the first modulator from causing variation in the output of the second modulator.

11. The processing device of claim 1, wherein
the first modulation scheme is a quadrature phase shift keying (QPSK) scheme and the second scheme is a pulse amplitude modulation (QAM) scheme, and
the plurality of modulators includes at least first and second modulators.

12. The processing device of claim 11, wherein
the signal processor is configured to provide a first input signal from among the plurality of input signals to an I branch of the first modulator and to provide a second input signal from among the plurality of input signals to a Q branch of the first modulator such that the first modulator generates a first output,
the signal processor is configured to provide a third input signal from among the plurality of input signals to an I branch of the second modulator and to provide a fourth input signal from among the plurality of input signals to a Q branch of the second modulator such that the second modulator generates a second output, and
the combiner is configured to generate the modulated output by combining the first and second outputs.

13. The processing device of claim 11 wherein the first and second modulators are configured such that an amplitude of the first output is twice an amplitude of the second output.

14. The processing device of claim 11 wherein
the plurality of modulators includes a third modulator,
the signal processor is configured to provide a fifth input signal from among the plurality of input signals to an I branch of the third modulator and to provide a sixth input signal from among the plurality of input signals to a Q branch of the third modulator such that the third modulator generates a third output, and
the combiner is configured to generate the modulated output by combining the first, second and third outputs.

15. The processing device of claim 14 wherein the first, second and third modulators are configured such that an amplitude of the first output is twice an amplitude of the second output, and an amplitude of the second output is twice an amplitude of the third output.

16. A method of modulating a bit stream, the method comprising:
converting the bit stream into a plurality of input signals;
providing the plurality of input signals to a plurality of modulators, each of the plurality of modulators performing modulation according to a same first modulation scheme,
generating outputs from the plurality of modulators, and
combining the outputs from the plurality of modulators to generate a modulated signal, the plurality of input signals being provided to the plurality of modulators in such a manner that the combining of the outputs generates the modulated signal according to a second modulation scheme.

17. The method of claim 16, wherein
the first modulation scheme is a quadrature phase shift keying (QPSK) scheme and the second modulation scheme is a rotated QPSK scheme, and
the plurality of modulators includes at least first and second modulators.

18. The method of claim 17, wherein
the generating step includes
generating a first output from the first modulator by providing a first input signal from among the plurality of input signals to a Q branch of the first modulator and providing a fixed signal to an I branch of the first modulator, and
generating a second output from the second modulator by providing a second input signal from among the plurality of input signals to an I branch of the second modulator and providing a fixed signal to a Q branch of the second modulator.

19. The method claim 17, wherein the first and second outputs have first and second amplitudes, respectively, the first and second amplitudes being selected to provide a desired amount of rotation for a rotated constellation (X,Y).

20. The method of claim 19, wherein the rotated constellation (X,Y) is defined as
$$( \begin{matrix}X \\ Y\end{matrix} ) = ( \begin{matrix}cos Θ & sin Θ \\ - sin Θ & cos Θ\end{matrix} ) ( \begin{matrix}A \\ B\end{matrix} ) ,$$
where A is the first amplitude, B is the second amplitude, Θ=π/4−α, and α=arctan(A/B).

21. The method of claim 17, wherein the fixed signal provided to the first modulator prevents the I branch of the first modulator from causing variation in the output of the first modulator, and the fixed signal provided to the second modulator prevents the Q branch of the second modulator from causing variation in the output of the second modulator.

22. The method of claim 16, wherein
the first modulation scheme is a quadrature phase shift keying (QPSK) scheme and the second modulation scheme is a pulse amplitude modulated (PAM) scheme,
the plurality of modulators includes at least first and second modulators.

23. The method of claim 22, wherein
the generating step includes
generating a first output from the first modulator by providing a first input signal from among the plurality of input signals to an I branch of the first modulator and providing a fixed signal to a Q branch of the first modulator, and
generating a second output from the second modulator by providing a second input signal from among the plurality of input signals to an I branch of a second modulator and providing a fixed signal to a Q branch of the second modulator.

24. The method of claim 22 wherein an amplitude of the first output is twice an amplitude of the second output.

25. The method of claim 22 wherein the fixed signal provided to the first modulator prevents the Q branch of the first modulator from causing variation in the output of the first modulator, and the fixed signal provided to the second modulator prevents the Q branch of the second modulator from causing variation in the output of the second modulator.

26. The method of claim 16, wherein
the first modulation scheme is a quadrature phase shift keying (QPSK) scheme and the second modulation scheme is a quadrature amplitude modulated (QAM) scheme, and
the plurality of modulators includes at least first and second modulators.

27. The method of claim 26, wherein
the generating step includes
generating a first output from the first modulator by providing a first input signal from among the plurality of input signals to a Q branch of a first modulator and providing a second input signal from among the plurality of input signals to an I branch of the first modulator, and
generating a second output from the second modulator by providing a third input signal from among the plurality of input signals to an I branch of the second modulator and providing a fourth input signal from among the plurality of input signals to a Q branch of the second modulator.

28. The method claim 26, wherein an amplitude of the first output is twice an amplitude of the second output.

29. The method of claim 26, wherein
the plurality of modulators includes a third modulator, and
the generating step further includes
generating a third output from the third modulator by providing a fifth input signal from among the plurality of input signals to a Q branch of a third modulator and providing a sixth input signal from among the plurality of input signals to an I branch of the third modulator.

30. The processing device of claim 29, wherein the first, second and third modulators are configured such that an amplitude of the first output is twice an amplitude of the second output, and an amplitude of the second output is twice an amplitude of the third output.

31. The method of claim 26 further comprising:
determining a desired spacing for a constellation corresponding to the modulated signal;
determining amplitudes of the outputs of the first and second modulators based on the desired spacing.
